(19) United States
(12) Patent Application Publication
(10) Pub. No.: US 2020/0411355 A1
(43) Pub. Date: Dec. 31, 2020

(54) APPARATUS FOR REDUCTION OR PREVENTION OF ARCING IN A SUBSTRATE SUPPORT

(71) Applicant: APPLIED MATERIALS, INC., Santa Clara, CA (US)

(72) Inventors: Hamid NOORBAKHSH, Oakland, CA (US); Anwar HUSAIN, PLEASANTON, CA (US); Kartik RAMASWAMY, San Jose, CA (US); Sergio Fukuda SHOJI, San Jose, CA (US); Reyn Tetsuro WAKABAYASHI, San Jose, CA (US)

(21) Appl. No.: 16/900,102

(22) Filed: Jun. 12, 2020

Related U.S. Application Data
(60) Provisional application No. 62/868,229, filed on Jun. 28, 2019.

(51) Int. Cl. H01L 21/683; H01L 21/67; H01J 37/32

(52) U.S. Cl. CPC H01L 21/6833; H01L 21/67017; H01J 2237/334; H01J 2237/002; H01J 37/32724

(57) ABSTRACT

Embodiments of a plug for use in an electrostatic chuck are provided herein. In some embodiments, a plug for use in an electrostatic chuck includes a polymer sleeve having a central opening; a core press-fit in the central opening of the polymer sleeve and having a gas flow channel disposed therethrough; a cap disposed on the polymer sleeve and covering the core, the cap having a through hole through the cap; and an annular channel disposed between the core and the cap, wherein the core, the cap, and the annular channel define a gas flow path through the plug.

### CROSS-REFERENCE TO RELATED APPLICATIONS

This application claims benefit of U.S. provisional patent application Ser. No. 62/868,229, filed Jun. 28, 2019 which is herein incorporated by reference in its entirety

### FIELD

Embodiments of the present disclosure generally relate to substrate processing systems, and more specifically, to electrostatic chucks for use in substrate processing systems.

### BACKGROUND

Electrostatic chucks are used for providing support to substrates within substrate processing systems, such as a plasma processing chamber. A type of electrostatic chuck includes holes to flow heat transfer fluid such as a gas between a support surface of the electrostatic chuck and a backside of the substrate. Generally, the gas fills the area between the electrostatic chuck and the substrate to enhance the uniformity and rate of heat transfer between the electrostatic chuck and the substrate.

In plasma processing chambers, the electrostatic chuck is subjected to high power radio frequency (RF) fields and high density plasmas in the vicinity of the substrate. In such plasma processing chambers, gas breakdown due to high electric field generation in the gas passages can undesirably occur. The inventors have observed that plasma formation in the holes can lead to arcing, especially in regions having high power radio frequency (RF) fields.

Accordingly, the inventors have provided an improved electrostatic chuck.

### SUMMARY

Methods and apparatus of a plug for use in an electrostatic chuck are provided herein. In some embodiments, a plug for use in an electrostatic chuck includes a polymer sleeve having a central opening; a core press-fit in the central opening of the polymer sleeve and having a gas flow channel disposed therethrough; a cap disposed on the polymer sleeve and covering the core, the cap having a step on one side; and an annular channel disposed between the core and the cap, wherein the core, the cap, and the annular channel define a gas flow path through the plug.

In some embodiments, an electrostatic chuck for use in a substrate processing chamber includes a metallic base plate having an upper surface opposite a lower surface; a dielectric plate disposed on the metallic base plate, wherein the dielectric plate has a lower surface that includes a cavity; an electrode embedded in the dielectric plate; a plug comprising a ceramic core disposed in the cavity; and a gas flow path extending from the lower surface of the metallic base plate and about the ceramic core to an upper surface of the dielectric plate, wherein the gas flow path about the ceramic plug extends at an angle with respect to the upper surface of the metallic base plate.

In some embodiments, an electrostatic chuck for use in a substrate processing chamber, includes a metallic base plate having an upper surface opposite a lower surface; a dielectric plate having an electrode disposed on the metallic base plate and having an upper surface opposite a lower surface, wherein the upper surface includes a substrate receiving surface and the lower surface has a plurality of cavities; a plug disposed in each one of the plurality of cavities, wherein the plug includes a spiral channel; a gas flow path extending from the lower surface of the metallic base plate through the spiral channel to the upper surface of the dielectric plate; and a porous puck disposed in the gas flow path in the metallic base and opposite the plug.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber having an electrostatic chuck in accordance with at least some embodiments of the present disclosure.

FIG. 2 depicts a schematic side view of an electrostatic chuck in accordance with at least some embodiments of the present disclosure.

FIG. 3 depicts a partial cross-sectional side view of an electrostatic chuck in accordance with at least some embodiments of the present disclosure.

FIG. 4 depicts a partial cross-sectional side view of an electrostatic chuck in accordance with at least some embodiments of the present disclosure.

FIG. 5 depicts a partial cross-sectional side view of an electrostatic chuck in accordance with at least some embodiments of the present disclosure.

FIG. 6 depicts a partial cross-sectional side view of an electrostatic chuck in accordance with at least some embodiments of the present disclosure.

FIG. 7A depicts a partial cross-sectional side view of an electrostatic chuck in accordance with at least some embodiments of the present disclosure.

FIG. 7B depicts a top view of a plug depicted in FIG. 7A.

FIG. 7C depicts a bottom view of the plug depicted in FIG. 7A.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of electrostatic chucks for use in a substrate processing chamber are provided herein. The electrostatic chuck includes a dielectric plate having a support surface to support a substrate. The dielectric plate is disposed on a metallic base plate. In some embodiments, one or more gas channels extend from a bottom surface of the electrostatic (e.g., bottom surface of the metallic base plate) to a top surface of the electrostatic chuck (e.g., top surface of the dielectric plate). The one or more gas channels are configured to provide backside gas, such as nitrogen (N) or helium (He), to the top surface of the electrostatic chuck to act as a heat transfer medium.

In some embodiments, a RF power source is coupled to the metallic base plate and configured to provide negative bias to a substrate being processed. As RF power is applied to the metallic base plate, a voltage on the metallic base plate and on the substrate is different depending on the impedance of the dielectric plate. The difference in respective voltages creates an electric field between the metallic base plate and the substrate, which can undesirably cause backside gas to be ionized and consequently lead to arcing.

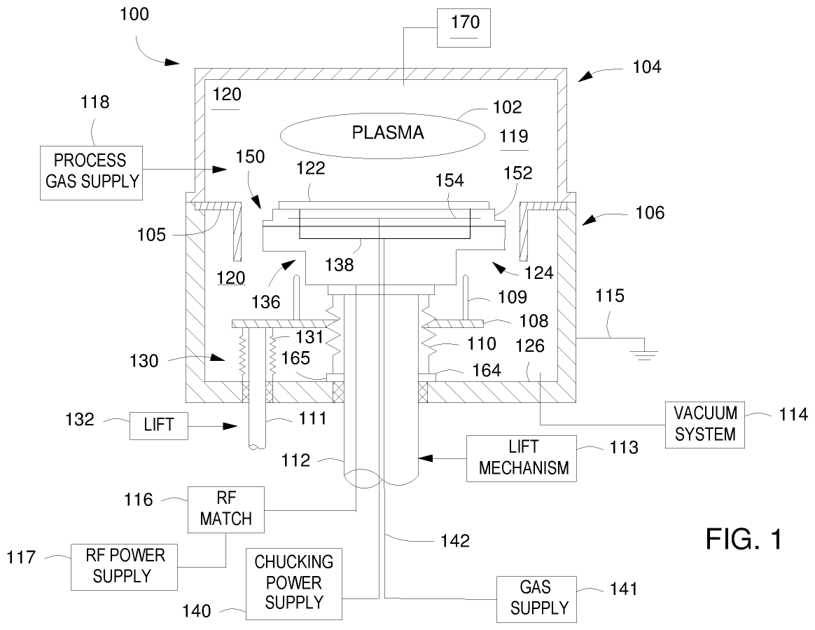

FIG. 1 depicts a schematic side view of a process chamber (e.g., a plasma processing chamber) having an electrostatic chuck in accordance with at least some embodiments of the present disclosure. In some embodiments, the plasma processing chamber is an etch processing chamber. However, other types of processing chambers configured for different processes can also use or be modified for use with embodiments of the electrostatic chuck described herein.

The chamber 100 is a vacuum chamber which is suitably adapted to maintain sub-atmospheric pressures within a chamber interior volume 120 during substrate processing. The chamber 100 includes a chamber body 106 covered by a lid 104 which encloses a processing volume 119 located in the upper half of chamber interior volume 120. The chamber 100 may also include one or more shields 105 circumscribing various chamber components to prevent unwanted reaction between such components and ionized process material. The chamber body 106 and lid 104 may be made of metal, such as aluminum. The chamber body 106 may be grounded via a coupling to ground 115.

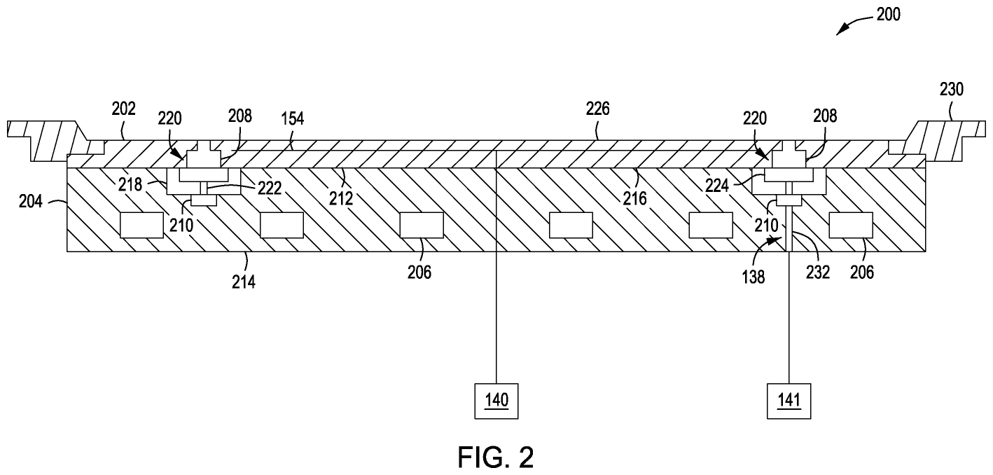

A substrate support 124 is disposed within the chamber interior volume 120 to support and retain a substrate 122, such as a semiconductor wafer, for example, or other such substrate as may be electrostatically retained. The substrate support 124 may generally comprise an electrostatic chuck 150 (described in more detail below with respect to FIGS. 2-6) and a hollow support shaft 112 for supporting the electrostatic chuck 150. The electrostatic chuck 150 comprises a dielectric plate 152 having one or more electrodes 154 disposed therein and a metallic base plate 136. The hollow support shaft 112 provides a conduit to provide, for example, backside gases, process gases, fluids, coolants, power, or the like, to the electrostatic chuck 150.

In some embodiments, the hollow support shaft 112 is coupled to a lift mechanism 113, such as an actuator or motor, which provides vertical movement of the electrostatic chuck 150 between an upper, processing position (as shown in FIG. 1) and a lower, transfer position (not shown). A bellows assembly 110 is disposed about the hollow support shaft 112 and is coupled between the electrostatic chuck 150 and a bottom surface 126 of chamber 100 to provide a flexible seal that allows vertical motion of the electrostatic chuck 150 while preventing loss of vacuum from within the chamber 100. The bellows assembly 110 also includes a lower bellows flange 164 in contact with an o-ring 165 or other suitable sealing element which contacts the bottom surface 126 to help prevent loss of chamber vacuum.

The hollow support shaft 112 provides a conduit for coupling a backside gas supply 141, a chucking power supply 140, and RF sources (e.g., RF plasma power supply 170 and RF bias power supply 117) to the electrostatic chuck 150. The backside gas supply 141 is disposed outside of the chamber body 106 and supplies heat transfer gas to the electrostatic chuck 150. In some embodiments, RF plasma power supply 170 and RF bias power supply 117 are coupled to the electrostatic chuck 150 via respective RF match networks (only RF match network 116 shown). In some embodiments, the substrate support 124 may alternatively include AC, DC, or RF bias power.

A substrate lift 130 can include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150. The electrostatic chuck 150 may include thru-holes to receive the lift pins 109. A bellows assembly 131 is coupled between the substrate lift 130 and bottom surface 126 to provide a flexible seal which maintains the chamber vacuum during vertical motion of the substrate lift 130.

The electrostatic chuck 150 includes gas distribution channels 138 extending from a lower surface of the electrostatic chuck 150 to various openings in an upper surface of the electrostatic chuck 150. The gas distribution channels 138 are in fluid communication with the backside gas supply 141 via gas conduit 142 to control the temperature and/or temperature profile of the electrostatic chuck 150 during use.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein.

In operation, for example, a plasma 102 may be created in the chamber interior volume 120 to perform one or more processes. The plasma 102 may be created by coupling power from a plasma power source (e.g., RF plasma power supply 170) to a process gas via one or more electrodes near or within the chamber interior volume 120 to ignite the process gas and creating the plasma 102. A bias power may also be provided from a bias power supply (e.g., RF bias power supply 117) to the one or more electrodes 154 within the electrostatic chuck 150 to attract ions from the plasma towards the substrate 122.

FIG. 2 depicts a schematic side view of an electrostatic chuck 200 in accordance with at least some embodiments of the present disclosure. In some embodiments, the electrostatic chuck 200 is the electrostatic chuck 150 as discussed above with respect to FIG. 1. The electrostatic chuck 200 includes a metallic base plate 204 having an upper surface 212 opposite a lower surface 214. In some embodiments, the metallic base plate 204 is made of aluminum (Al). In some embodiments, the metallic base plate 204 includes cooling channels 206 configured to flow a coolant therethrough.

A dielectric plate 202 is disposed on and coupled to the metallic base plate 204. In some embodiments, the dielectric plate 202 is made of aluminum nitride (AlN). One or more electrodes 154 are embedded in the dielectric plate 202 and coupled to the chucking power supply 140. The dielectric plate 202 has a lower surface 216 opposite an upper surface 226. The upper surface 226 corresponds with a substrate receiving surface. The lower surface 216 includes one or more cavities 208. In some embodiments, an edge ring 230 is disposed at least one of on or about the dielectric plate 202. In some embodiments, the edge ring 230 is made of silicon (Si).

In some embodiments, the one or more cavities 208 extend from the lower surface 216 to the upper surface 226. In some embodiments, the one or more cavities 208 extend from the lower surface 216 and partially through the dielectric plate 202. In some embodiments, the one or more cavities 208 are disposed about dielectric plate 202 at locations equidistant from a central axis of the dielectric plate 202. In some embodiments, the one or more cavities 208 are disposed in a peripheral region of the dielectric plate 202.

A plug 220 is disposed in each of the one or more cavities 208. In some embodiments, the plug 220 is advantageously press-fit into a respective cavity so that there is no gap therebetween, reducing the likelihood of arcing. In some embodiments, a top portion of the plug 220 is narrower than a bottom portion of the plug 220 to aid in placing and press-fitting the plug 220 into a respective cavity. The plug 220 (or any of the plugs discussed below) comprises aluminum oxide (Al₂O₃) or aluminum nitride (AlN), for example. The plug 220 (or any of the plugs discussed below) can comprise other materials.

A gas flow path extends from the lower surface 214 of the metallic base plate 204 to the upper surface 226 of the dielectric plate 202 via gas distribution channels 138 and the plug 220. In some embodiments, the gas distribution channels 138 include a first channel 232 extending from the lower surface 214 of the metallic base plate 204 to an annular channel 210 disposed in the metallic base plate 204. In some embodiments, the annular channel 210 is disposed in a peripheral region of the metallic base plate 204.

In some embodiments, a cap ring 218 is disposed between the upper surface of the 212 metallic base plate 204 and the annular channel 210 to cover the annular channel 210. In some embodiments, the cap ring 218 is made of the same material as the metallic base plate 204. In some embodiments, the cap ring 218 includes one or more porous pucks 224 disposed therein adjacent an upper surface of the cap ring 218. In some embodiments, the porous pucks 224 are made of ceramic or polymer. The porous pucks 224 are disposed opposite each of the one or more plugs 220. In some embodiments, the porous pucks 224 have a porosity of about 30% to about 60% (e.g., a percent open volume of the porous puck). In some embodiments, the cap ring 218 has a constant width. In some embodiments, the cap ring 218 is wider at portions corresponding with the porous pucks 225 and narrower therebetween. In some embodiments, the cap ring 218 includes one or more second channels 222 extending through the cap ring 218 to fluidly couple the annular channel 210 to the one or more porous pucks 224. The one or more porous pucks 224 are configured to facilitate a flow of gas from the one or more second channels 222 to the upper surface 212 of the metallic base plate 204.

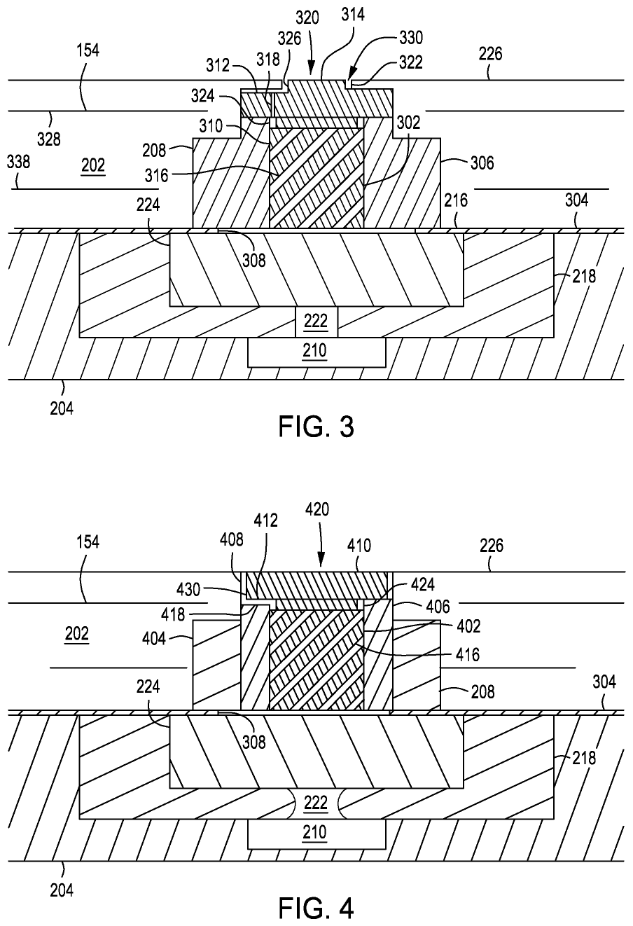

FIG. 3 depicts a partial cross-sectional side view of an electrostatic chuck in accordance with at least some embodiments of the present disclosure. In some embodiments, the metallic base plate 204 is bonded to the dielectric plate 202 with a bonding layer 304 disposed therebetween. The bonding layer 304 includes an opening 308 corresponding with a location of each of the one or more plugs 320 to facilitate gas flow from the metallic base plate to each of the one or more plugs 320. In some embodiments, the one or more electrodes 154 includes a first electrode 328 for chucking the substrate 122 and a second electrode 338 disposed below the edge ring 230 to advantageously provide plasma uniformity at an edge region of the electrostatic chuck 200.

A plug 320 may be the plug 220 discussed above with respect to FIG. 2. The plug 320 includes a core 302 and a polymer sleeve 306 is disposed in the cavity 208. The core 302 comprises a ceramic shaft. In some embodiments, the core is made of aluminum oxide (Al₂O₃) or aluminum nitride (AlN). The polymer sleeve 306 having a central opening 310 is disposed about the core 302. In some embodiments, the core 302 is advantageously press fit in the central opening 310 of the polymer sleeve 306 to prevent gaps therebetween. In some embodiments, the polymer sleeve is made of polytetrafluoroethylene. The polymer sleeve may be made of other suitable materials. The plug 320 extends from the lower surface 216 of the dielectric plate 202 to the upper surface 226 of the dielectric plate 202. In some embodiments, an outer sidewall of the polymer sleeve 306 includes one or more steps such that a top portion of the plug 320 is narrower than a bottom portion of the plug 320

A gas flow channel 316 is disposed between the core 302 and the polymer sleeve 306. The gas flow channel 316 extends at an angle with respect to the upper surface 212 of the metallic base plate 204. In some embodiments, the gas flow channel 316 includes a spiral channel about the core 302 that extends in a spiral pattern. In some embodiments, the spiral channel extends from a lower surface of the core 302 to an up upper surface of the core 302.

A cap 314 made of a ceramic material is disposed on the polymer sleeve 306 and covering the core 302. In some embodiments, the cap 314 is integrally formed with the core 302. The cap 314 includes a circular protrusion 326 extending away from the core 302 and a step 312 on one side. A through hole 318 is formed through the cap 314 from the step 312 to a bottom surface of the cap 314. In some embodiments, the through hole 318 is disposed radially outwards of the circular protrusion 326. In some embodiments, an upper surface of the circular protrusion 326 is coplanar with the upper surface 226 of the dielectric plate 202.

In some embodiments, an annular channel 324 is disposed between the core 302 and the cap 314. In some embodiments, an outer diameter of the circular protrusion 326 is less than a diameter of an opening 322 formed through the upper surface 226 of the dielectric plate 202 to create a second annular channel 330 between the circular protrusion 326 and the dielectric plate 202. The second annular channel 330 extends from the upper surface 226 to the step 312. The gas flow channel 316 of the core 302 and the through hole 318 of the cap 314 are each coupled to the annular channel 324. A gas flow path through the plug 320 is defined by the gas flow channel 316 of the core 302, the annular channel 324, the through hole 318, and the second annular channel 330.

FIG. 4 depicts a partial cross-sectional side view of an electrostatic chuck in accordance with at least some embodiments of the present disclosure. A plug 420 may be the plug 220 discussed above with respect to FIG. 2. The plug 420 includes a core 402 disposed in a polymer sleeve 406. In some embodiments, the core 402 is press fit into the polymer sleeve 406 to partially fill the cavity 208. A gas flow channel 416 having a spiral shape is disposed between the core 402 and the polymer sleeve 406. In some embodiments, as shown in FIG. 4, the plug 440 includes a silicone potting material 404 disposed about the polymer sleeve 406 to fill a gap between the polymer sleeve and the dielectric plate 202. The plug 420 extends from the lower surface 216 of the dielectric plate 202 to the upper surface 226 of the dielectric plate 202.

A cap 410 is disposed on the polymer sleeve 406 and covers the core 402. In some embodiments, the cap 410 is integrally formed with the core 402. An annular channel 424 is disposed between the core 402 and the cap 410. The cap 410 includes a step 412 on one side from a lower surface of the cap 410. In some embodiments, the cap 410 has no through holes and the gas flow path extends around the cap 410 In some embodiments, an upper surface of the cap 410 is coplanar with the upper surface 226 of the dielectric plate 202. An outer diameter of the cap 410 is less than a diameter of an opening 408 formed through the upper surface 226 of the dielectric plate 202 to create a second annular channel 430 between the cap 410 and the dielectric plate 202. The second annular channel 430 extends from the upper surface 226 to the step 412 and facilitates the gas flow path extending around the cap 410. The annular channel 424 is coupled to the second annular channel via a radial channel 418 defined by the step 412 and an upper surface of the polymer sleeve 406. In some embodiments, the annular channel 424 has a diameter less than a diameter of the second annular channel 430. A gas flow path through the plug 420 is defined by the gas flow channel 416 of the core 402, the annular channel 424, the radial channel 418, and the second annular channel 430.

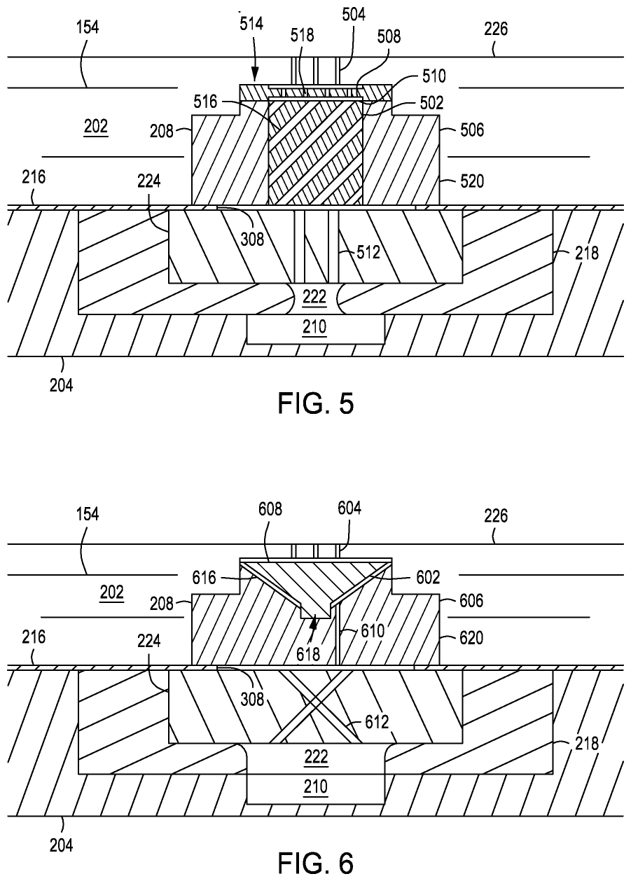

FIG. 5 depicts a partial cross-sectional side view of an electrostatic chuck in accordance with at least some embodiments of the present disclosure. A plug 520 may be the plug 220 discussed above with respect to FIG. 2. The plug 520 includes a core 502 disposed in a polymer sleeve 506. In some embodiments, the core 502 is press fit into the polymer sleeve 506. In some embodiments, the plug 520 is press fit into the cavity 208. A gas flow channel 516 having a spiral shape is disposed between the core 502 and the polymer sleeve 506. The plug 520 includes a cap 514 is disposed on the polymer sleeve 506 to cover the core 502. In some embodiments, the cap 514 has an outer diameter similar to an outer diameter of the polymer sleeve 506.

A top surface of the plug 520 is disposed within the dielectric plate 202. In some embodiments, one or more holes 504 extend from the top surface of the plug 520 to the upper surface 226 of the dielectric plate 202. In some embodiments, the cap 514 includes through holes 518 formed through the cap 514. In some embodiments, a lower surface of the cap 514 includes a first recess 508 opposite the core 502 to define a first plenum. In some embodiments, an upper surface of the cap 514 includes a second recess 510 to define a second plenum. A gas flow path through the plug 520 is defined by the gas flow channel 516 of the core 502, through holes 518, and holes 504. In some embodiments, the porous puck 224 includes vertical through holes 512 for increased gas flow through the porous puck 224.

FIG. 6 depicts a partial cross-sectional side view of an electrostatic chuck in accordance with at least some embodiments of the present disclosure. A plug 620 may be the plug 220 discussed above with respect to FIG. 2. The plug 620 includes a core 602 disposed in a sleeve 606. The core 602 has a triangular shaped body 608 and a tab 618 protruding from one of the corners of the triangular shaped body 608. In some embodiments, the tab 618 is press fit into the sleeve 606, with the tab 618 extending towards the lower surface 216 of the dielectric plate 202. In some embodiments, the core 502 is press fit into the polymer sleeve 506. In some embodiments, the core 602 and the sleeve 606 are made of a ceramic material.

A gap between sides of the triangular shaped body 608 and the sleeve 606 define a gas flow channel 616. In some embodiments, the gas flow channel 616 has a conical shape that expands in diameter as the gas flow channel 616 extends towards the upper surface 226 of the dielectric plate 202. A top surface of the plug 620 is disposed within the dielectric plate 202. In some embodiments, one or more holes 604 extend from the top surface of the plug 520 to the upper surface 226 of the dielectric plate 202. A channel 610 is disposed in the sleeve 606 and extends from the lower surface 216 of the dielectric plate 202 to the gas flow channel 616. In some embodiments, the channel 610 extends vertically. A gas flow path through the plug 620 is defined by the channel 610 of the sleeve 606, the gas flow channel 616, and through holes 604. In some embodiments, the porous puck 224 includes through holes 612 for increased gas flow through the porous puck 224. In some embodiments, through holes 612 extend at an angle with respect to an upper surface of the porous plug 244.

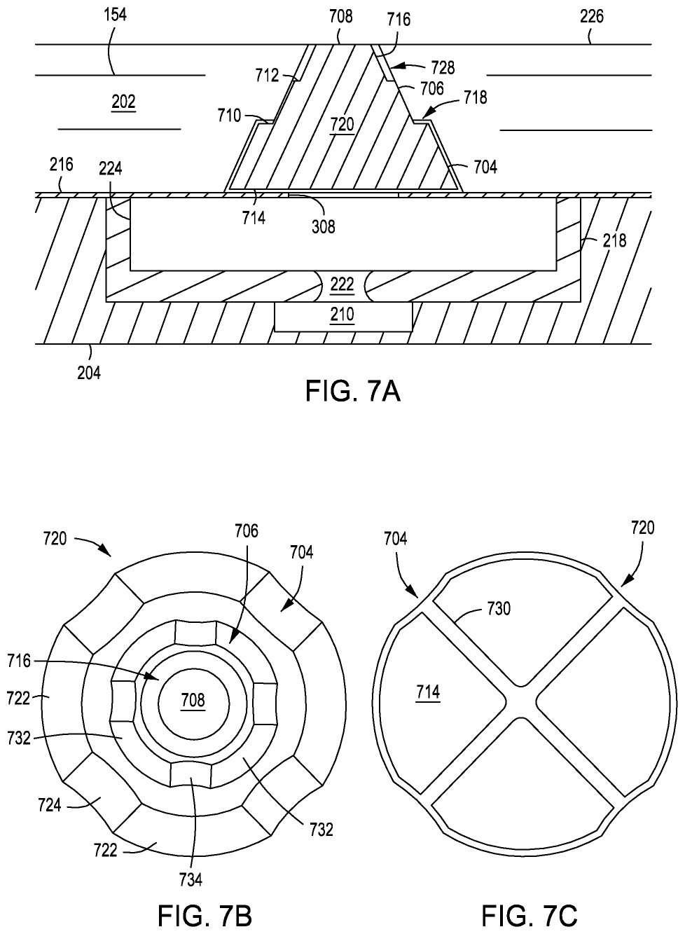

FIG. 7A depicts a partial cross-sectional side view of an electrostatic chuck in accordance with at least some embodiments of the present disclosure. A plug 720 may be the plug 220 discussed above with respect to FIG. 2. The plug 720 includes a lower portion 704, an upper portion 716, and a middle portion 706 disposed between the lower portion 704 and the upper portion 716. The lower portion 704, the middle portion 706, and the upper portion 716 all taper radially inward from a lower surface of the plug to an upper surface 708 of the plug 720. In some embodiments, the upper surface 708 is coplanar with the upper surface 226 of the dielectric plate 202. In some embodiments, a first annular step 710 is disposed between the lower portion 704 and the middle portion 706. In some embodiments, a second annular step 712 is disposed between the middle portion 706 and the upper portion 716.

FIGS. 7B and 7B depict a top view and a bottom view, respectively, of the plug 720. In some embodiments, the lower portion 704 includes one or more first flat portions 724 disposed between a plurality of first curved portions 722. In some embodiments, the middle portion 706 includes one or more second flat portions 734 disposed between a plurality of second curved portions 732. In some embodiments, the first flat portions 724 are oriented to correspond with the second curved portions 732, and the first curved portions 722 are oriented to correspond with the second flat portions 734. The plug 720 is sized such that there is no gap between sidewalls of the cavity 208 and the first curved portions 722 and the second curved portions 732. There is a gap between the sidewalls of the cavity 208 and the first flat portions 724 and the second flat portions 734 to partially define a gas flow path through the plug 720.

In some embodiments, a plurality of grooves 730 are disposed on a lower surface 714 of the plug 720. The plurality of grooves 730 extend to each of the first flat portions 724. In some embodiments, the plurality of grooves 730 form a plus shape to extend to four first flat portions 724. The first annular step 710 and a surface of the cavity 208 define a first annular channel 718. The second annular step 712 and a surface of the cavity 208 define a second annular channel 728 about the upper portion 716. In some embodiments, a gas flow path through the plug 720 is defined by the plurality of grooves 730, the first flat portions 724, the first annular channel 718, the second flat portions 734, and the second annular channel 728.

While the foregoing is directed to embodiments of the present disclosure, other and further embodiments of the disclosure may be devised without departing from the basic scope thereof.

1. A plug for use in an electrostatic chuck, comprising:
a polymer sleeve having a central opening;
a core press-fit in the central opening of the polymer sleeve and having a gas flow channel disposed therethrough;
a cap disposed on the polymer sleeve and covering the core; and
an annular channel disposed between the core and the cap, wherein the core, the cap, and the annular channel define a gas flow path through the plug.

2. The plug of claim 1, wherein the cap has a circular protrusion, a step on one side, and a through hole is formed through the cap from the step to a bottom surface of the cap, wherein the core and the through hole of the cap define the gas flow path through the plug.

3. The plug of claim 1, wherein the cap has no through holes and the gas flow path extends around the cap.

4. The plug of claim 1, wherein a top portion of the plug is narrower than a bottom portion of the plug.

5. The plug of claim 1, wherein the polymer sleeve is made of polytetrafluoroethylene.

6. The plug of claim 1, wherein the core is made of aluminum oxide (Al₂O₃) or aluminum nitride (AlN).

7. The plug of claim 1, wherein the gas flow path extends through a spiral channel about the core from a lower surface of the core to an up upper surface of the core.

8. The plug of claim 1, further comprising silicone potting material disposed about the polymer sleeve.

9. An electrostatic chuck for use in a substrate processing chamber, comprising:
a metallic base plate having an upper surface opposite a lower surface;
a dielectric plate disposed on the metallic base plate, wherein the dielectric plate has a lower surface that includes a cavity;
an electrode embedded in the dielectric plate;
a plug comprising a ceramic core disposed in the cavity; and
a gas flow path extending from the lower surface of the metallic base plate and about the ceramic core to an upper surface of the dielectric plate, wherein the gas flow path about the ceramic core extends at an angle with respect to the upper surface of the metallic base plate.

10. The electrostatic chuck of claim 9, further comprising a porous puck disposed in the gas flow path in the metallic base plate and opposite the plug.

11. The electrostatic chuck of claim 9, wherein the cavity is disposed at a peripheral region of the dielectric plate.

12. The electrostatic chuck of claim 9, wherein the plug extends from the lower surface of the dielectric plate to the upper surface of the dielectric plate.

13. The electrostatic chuck of claim 9, wherein a top surface of the plug is disposed within the dielectric plate and one or more holes extend from the top surface of the plug to the upper surface of the dielectric plate.

14. The electrostatic chuck of claim 9, wherein the plug includes a ceramic shaft surrounded by a polymer sleeve and the gas flow path extends therebetween.

15. The electrostatic chuck of claim 14, wherein the gas flow path extends about the ceramic shaft in a spiral pattern defined by the ceramic shaft.

16. The electrostatic chuck of claim 14, wherein the plug further comprises a ceramic cap disposed on the ceramic shaft and the polymer sleeve, wherein an upper surface of the ceramic cap is substantially coplanar with the upper surface of the dielectric plate.

17. An electrostatic chuck for use in a substrate processing chamber, comprising:
a metallic base plate having an upper surface opposite a lower surface;
a dielectric plate disposed on the metallic base plate and having an upper surface opposite a lower surface, wherein the upper surface includes a substrate receiving surface and the lower surface has a plurality of cavities;
an electrode embedded in the dielectric plate;
a plug disposed in each one of the plurality of cavities, wherein the plug includes a spiral channel;
a gas flow path extending from the lower surface of the metallic base plate through the spiral channel to the upper surface of the dielectric plate; and
a porous puck disposed in the gas flow path in the metallic base plate and opposite the plug.

18. The electrostatic chuck of claim 17, wherein the metallic base plate is made of aluminum (Al).

19. The electrostatic chuck of claim 17, wherein the dielectric plate is made of aluminum nitride (AlN).

20. The electrostatic chuck of claim 17, wherein the gas flow path at the upper surface of the dielectric plate is defined by at least one of an annular channel or a plurality of holes.
